(19) United States
(12) Patent Application Publication
(10) Pub. No.: US 2024/0128064 A1
(43) Pub. Date: Apr. 18, 2024

(54) COMPONENT REPLACEMENT METHOD, COMPONENT REPLACEMENT DEVICE, AND COMPONENT REPLACEMENT SYSTEM

(71) Applicant: Tokyo Electron Limited, Tokyo (JP)

(72) Inventors: Hiroki ENDO, Miyagi (JP); Suguru SATO, Miyagi (JP)

(73) Assignee: Tokyo Electron Limited, Tokyo (JP)

(21) Appl. No.: 18/025,934

(22) PCT Filed: May 27, 2022
(86) PCT No.: PCT/JP2022/021783

§ 371 Date: Mar. 13, 2023

(30) Foreign Application Priority Data
Jun. 3, 2021 (JP) 2021-093459

(51) Int. Cl. H01J 37/32; H01J 37/244

(52) U.S. Cl. CPC H01J 37/32807; H01J 37/244; H01J 37/3244; H01J 37/32862; H01J 2237/24578

(57) ABSTRACT

There is provided a component replacement method comprising: a) connecting a component replacement device to a chamber of a processing device configured to process a substrate; b) inserting an end effector disposed at a tip end of a transfer arm in the component replacement device into the chamber, and measuring a first distance from a predetermined position in the chamber to the end effector using a distance sensor provided on the end effector; c) moving the end effector until a difference between the first distance and a predetermined second distance becomes less than a predetermined third distance; d) capturing a feature disposed at a predetermined position in the chamber by a camera provided on the end effector; e) moving the end effector so that the feature is captured in a predetermined position in an image captured by the camera; and f) replacing a component in the chamber using the end effector with reference to a position of the end effector in a state where the feature is captured in the predetermined position in the image captured by the camera.

### TECHNICAL FIELD

Various aspects and embodiments of the present disclosure relate to a component replacement method, a component replacement device, and a component replacement system.

### BACKGROUND

Consumable components that are consumed by processing a substrate are disposed in a processing device for processing a substrate. The consumable components are replaced with unused consumable components when the amount of consumption exceeds a predetermined consumption amount. In the case of replacing consumable components, the processing of the substrate in the processing device is stopped, and the container of the processing device is opened to the atmosphere. Then, used consumable components are taken out manually, and unused consumable components are installed. Then, the container is closed again and evacuated to resume the processing of the substrate.

In the case of replacing consumable components, the inside of the processing device is exposed to the atmosphere, so that it is necessary to evacuate the inside of the processing device after the replacement of the consumable components, which increases a period of time in which the processing is stopped. Further, since consumable components include large-sized components, manual replacement may require a long period of time.

In order to avoid this, a replacement station including a replacement handler for replacing consumable components and unused consumable components is known (see, for example, the following Patent Document 1). In the replacement station, the processing device and the replacement station are connected, and a shutoff valve between the processing device and the replacement station is opened after the inside of the replacement station is evacuated. The replacement handler in the replacement station takes out used consumable components from the processing device and replaces them with unused consumable components in the replacement station. Accordingly, the consumable components can be replaced without opening the inside of the processing device to the atmosphere, and a period of time in which the processing is stopped can be shortened. Further, since the replacement of consumable components is performed not manually but by the replacement handler, the replacement of the consumable components can be performed within a short period of time.

### PRIOR ART DOCUMENTS

### Patent Documents

Patent Document 1: Japanese Laid-open Patent Publication No. 2017-85072

### SUMMARY

### Problems to be Resolved by the Invention

The present disclosure provides a component replacement method, a component replacement device, and a component replacement system capable of replacing a component in a chamber after accurately positioning a transfer arm with respect to the chamber.

### Means for Solving the Problems

One aspect of the present disclosure is a component replacement method including steps a), b), c), d), e), and f). In step a), a component replacement device is connected to a chamber of a processing device for processing a substrate. In step b), a transfer arm in the component replacement device is inserted into the chamber, and a first distance from a predetermined position in the chamber to the transfer arm is measured by a distance sensor installed at the transfer arm. In step c), the transfer arm is moved until the difference between the first distance and a predetermined second distance becomes less than a predetermined third distance. In step d), a feature disposed at a predetermined position in the chamber is captured by a camera installed at the transfer arm. In step e), the transfer arm is moved so that the feature is captured in a predetermined position in an image captured by the camera. In step f), a component in the chamber is replaced using the transfer arm with reference to a position of the transfer arm at a state where the feature is captured in the predetermined position in the image captured by the camera.

### Effect of the Invention

In accordance with various aspects and embodiments of the present disclosure, it is possible to replace a component in a chamber after positioning a transfer arm with respect to the chamber.

### BRIEF DESCRIPTION OF THE DRAWINGS

FIG. 1 is a system configuration diagram showing an example of a plasma processing system in a first embodiment.

FIG. 2 is a schematic cross-sectional view showing an example of the component replacement device in the first embodiment.

FIG. 3 is a plan view showing an example of an end effector in the first embodiment.

FIG. 4 is a flowchart showing an example of a component replacement method in the first embodiment.

FIG. 5 shows an example of a component replacement process.

FIG. 6 shows an example of the component replacement process.

FIG. 7 shows an example of an image captured by a camera.

FIG. 8 shows an example of an image captured by the camera.

FIG. 9 shows an example of an image captured by the camera.

FIG. 10 shows an example of the component replacement process.

FIG. 11 shows an example of the component replacement process.

FIG. 12 shows an example of the component replacement process.

FIG. 13 shows an example of the component replacement process.

FIG. 14 shows an example of the component replacement process.

FIG. 15 shows an example of the component replacement process.

FIG. 16 is a flowchart showing an example of a component replacement method in a second embodiment.

FIG. 17 is a system configuration diagram showing an example of a component replacement system in a third embodiment.

FIG. 18 is a block diagram showing an example of a control device.

FIG. 19 is a system configuration diagram showing an example of a plasma processing system in the third embodiment.

FIG. 20 is a schematic cross-sectional view showing an example of a component replacement device in the third embodiment.

FIG. 21 shows an example of the component replacement process.

FIG. 22 shows an example of an image captured by the camera.

FIG. 23 shows an example of an image captured by the camera.

FIG. 24 shows an example of an image captured by the camera.

### DETAILED DESCRIPTION

Hereinafter, embodiments of a component replacement method, a component replacement device, and a component replacement system will be described in detail with reference to the accompanying drawings. Further, the following embodiments are not intended to limit the component replacement method, the component replacement device, and the component replacement system of the present disclosure.

When a component replacement device for replacing a component is connected to a processing device for processing a substrate, the connection state between the processing device and the component replacement device may be different from a designed connection state due to the connection position of the component replacement device with respect to the processing device, the dimensional errors of the processing device and the component replacement device, or the like. If the connection state between the processing device and the component replacement device is different from the designed connection state, the coordinate system for the transfer arm in the component replacement device is misaligned with the coordinate system in the processing device, so that it is difficult to remove a used component from the processing device. Even if it is possible to remove the component, the removed component is placed on the transfer arm at a position misaligned with a predetermined position, so that the component may fall from the transfer arm during transfer or it is difficult to store the component in a container accommodating used components.

Further, when the coordinate system for the transfer arm in the component replacement device is misaligned with the coordinate system in the processing device, it is difficult to install an unused component in the processing device by the transfer arm. Even if it is possible to install the unused component, the unused component is installed at a position misaligned with the predetermined position in the processing device, which may change the characteristics of the processing performed by the processing device.

Therefore, the present disclosure provides a technique capable of replacing a component in the chamber after accurately positioning the transfer arm with respect to the chamber.

### First Embodiment

[Configuration of Plasma Processing System 100]

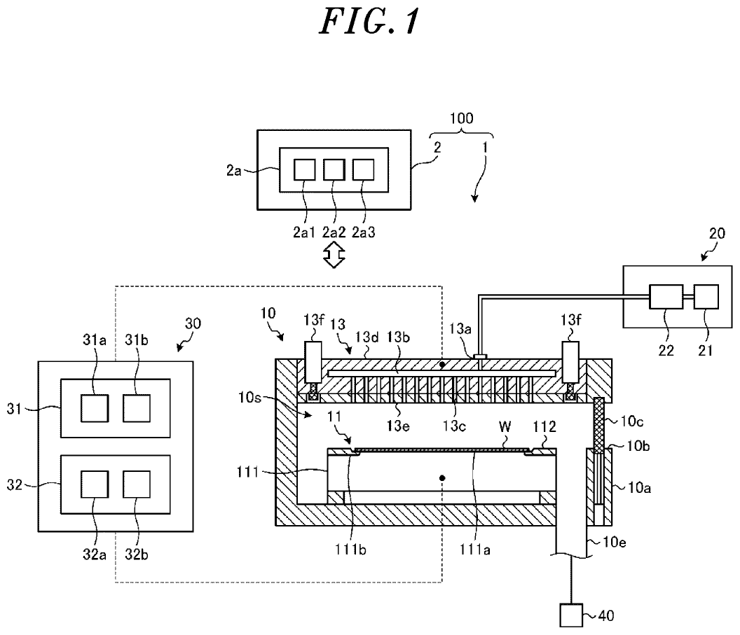

Hereinafter, a configuration example of a plasma processing system 100 will be described. FIG. 1 shows an example of the plasma processing system 100 in a first embodiment. The plasma processing system 100 includes a capacitively coupled plasma processing apparatus 1 and a controller 2. The plasma processing system 100 is an example of a processing apparatus for processing a substrate W. The plasma processing apparatus 1 includes a plasma processing chamber 10, a gas supply device 20, a power supply 30, and an exhaust system 40. Further, the plasma processing apparatus includes a substrate support 11 and a gas introducing member. The gas introducing member is configured to introduce at least one processing gas into the plasma processing chamber 10. The gas introducing member includes a shower head 13. The substrate support 11 is disposed in the plasma processing chamber 10. The shower head 13 is disposed above the substrate support 11. In one embodiment, the shower head 13 constitutes at least a part of the ceiling of the plasma processing chamber 10.

The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas to the plasma processing space 10s and at least one gas exhaust port for exhausting a gas from the plasma processing space 10s. The sidewall 10a is grounded. An opening 10b is formed on the sidewall 10a. The opening 10b is opened and closed by a gate valve 10c. The shower head 13 and the substrate support are electrically insulated from the housing of the plasma processing chamber 10.

The substrate support 11 includes a main body 111 and a ring assembly 112. The main body 111 has a substrate supporting surface 111a that is a central area for supporting the substrate W and a ring supporting surface 111b that is an annular area for supporting the ring assembly 112. The substrate W may also be referred to as “wafer.” The ring supporting surface 111b of the main body 111 surrounds the substrate supporting surface 111a of the main body 111 in plan view. The substrate W is placed on the substrate supporting surface 111a of the main body 111, and the ring assembly 112 is placed on the ring supporting surface 111b of the main body to surround the substrate W on the substrate supporting surface 111a of the main body 111.

In one embodiment, the main body 111 includes an electrostatic chuck and a base. The base has a conductive member. The conductive member of the base functions as a lower electrode. The electrostatic chuck is disposed on the base. The upper surface of the electrostatic chuck serves as the substrate supporting surface 111a.

The ring assembly 112 includes one or multiple annular members. At least one of the annular members is an edge ring. Although not shown, the substrate support 11 may include a temperature control module configured to control at least one of the electrostatic chuck, the ring assembly 112, and the substrate W to a target temperature. The temperature control module may include a heater, a heat transfer medium, a channel, or a combination thereof. A heat transfer fluid, such as brine or a gas, flows through the channel. The substrate support 11 may include a heat transfer gas supply device configured to supply a heat transfer gas to the gap between the substrate W and the substrate supporting surface 111a.

The shower head 13 is configured to introduce at least one processing gas from the gas supply device 20 into the plasma processing space 10s. The shower head 13 has at least one gas supply port 13a, at least one gas diffusion space 13b, and a plurality of gas inlet ports 13c. The processing gas supplied to the gas supply port 13a passes through the gas diffusion space 13b and is introduced into the plasma processing space 10s through the gas inlet ports 13c. The shower head 13 includes a conductive member. The conductive member of the shower head 13 functions as an upper electrode. The gas introducing member may include, in addition to the shower head 13, one or more side gas injectors (SGI) attached to one or multiple openings formed in the sidewall 10a.

The shower head 13 has an electrode support 13d and an upper electrode 13e. A holding mechanism 13f is disposed at the electrode support 13d. The holding mechanism 13f is, for example, an electric cam lock, and detachably fixes the upper electrode 13e to the bottom surface of the electrode support 13d. The holding mechanism 13f is controlled by the controller 2. In the present embodiment, the upper electrode 13e is an example of a replaceable component. Further, in the present embodiment, a marker having a predetermined shape is attached to the bottom surface of the upper electrode 13e. The marker is an example of a feature disposed at a predetermined position in the plasma processing chamber 10. In the present embodiment, the marker is, for example, a region having a predetermined shape and painted with a color different from that of the bottom surface of the upper electrode 13e. Further, the marker may be a concave portion or a convex portion formed on the bottom surface of the upper electrode 13e.

The gas supply device 20 may include at least one gas source 21 and at least one flow rate controller 22. In one embodiment, the gas supply device 20 is configured to supply at least one processing gas from the corresponding gas source through the corresponding flow rate controller 22 to the shower head 13. The flow rate controllers 22 may include, for example, a mass flow controller or a pressure-controlled flow rate controller. Further, the gas supply device 20 may include one or more flow modulation devices for modulating the flow rate of at least one processing gas or causing it to pulsate.

The power supply 30 includes a radio frequency (RF) power supply 31 coupled to the plasma processing chamber 10 through at least one impedance matching circuit. The RF power supply 31 is configured to provide at least one RF signal, such as a source RF signal and a bias RF signal, to one or both of the conductive member of the substrate support 11 and the conductive member of the shower head 13. Accordingly, plasma is produced from at least one processing gas supplied to the plasma processing space 10s. Therefore, the RF power supply 31 may function as at least a part of a plasma generator configured to generate plasma from one or more processing gases in the plasma processing chamber 10. Further, by supplying the bias RF signal to the conductive member of the substrate support 11, a bias potential is generated at the substrate W, and ions in the produced plasma can be attracted to the substrate W.

In one embodiment, the RF power supply 31 includes a first RF generator 31a and a second RF generator 31b. The first RF generator 31a is coupled to one or both of the conductive member of the substrate support 11 and the conductive member of the shower head 13 through at least one impedance matching circuit, and is configured to generate a source RF signal for plasma generation. The source RF signal may be referred to as “source RF power.” In one embodiment, the source RF signal has a frequency within a range of 13 MHz to 150 MHz. In one embodiment, the first RF generator 31a may be configured to generate a plurality of source RF signals having different frequencies. The generated one or multiple source RF signals are supplied to one or both of the conductive member of the substrate support 11 and the conductive member of the shower head 13.

The second RF generator 31b is coupled to the conductive member of the substrate support 11 through at least one impedance matching circuit, and is configured to generate a bias RF signal. The bias RF signal may be referred to as “bias RF power.” In one embodiment, the bias RF signal has a frequency lower than that of the source RF signal. In one embodiment, the bias RF signal has a frequency within a range of 400 kHz to 13.56 MHz. In one embodiment, the second RF generator 31b may be configured to generate multiple bias RF signals having different frequencies. One or multiple bias RF signals generated are supplied to the conductive member of the substrate support 11. Further, in various embodiments, at least one of the source RF signal and the bias RF signal may pulsate.

The power supply 30 may include a direct current (DC) power supply 32 coupled to the plasma processing chamber 10. The DC power supply 32 includes a first DC generator 32a and a second DC generator 32b. In one embodiment, the first DC generator 32a is connected to the conductive member of the substrate support 11, and is configured to generate a first DC signal. The generated first DC signal is applied to the conductive member of the substrate support 11. In another embodiment, the first DC signal may be applied to another electrode, such as an electrode 1110a in an electrostatic chuck 1110. In one embodiment, the second DC generator 32b is connected to the conductive member of the shower head 13, and is configured to generate a second DC signal. The generated second DC signal is applied to the conductive member of the shower head 13. In various embodiments, at least one of the first DC signal and the second DC signal may pulsate. Further, the first DC generator 32a and the second DC generator 32b may be provided in addition to the RF power supply 31, and the first DC generator 32a may be provided instead of the second RF generator 31b.

The exhaust system 40 may be connected to a gas exhaust port 10e disposed at the bottom of the plasma processing chamber 10, for example. The exhaust system 40 may include a pressure control valve and a vacuum pump. The pressure control valve adjusts a pressure in the plasma processing space 10s. The vacuum pump may include a turbo molecular pump, a dry pump, or a combination thereof.

The controller 2 processes computer-executable instructions that cause the plasma processing apparatus 1 to perform the various steps described in the present disclosure. The controller 2 may be configured to control individual components of the plasma processing apparatus 1 to perform various steps described herein. In one embodiment, the controller 2 may be partially or entirely included in the plasma processing apparatus 1. The controller 2 may include, e.g., a computer 2a. The computer 2a may include, e.g., a processor 2a1, a storage device 2a2, and a communication interface 2a3. The processor 2a1 may be configured to perform various operations based on a program stored in the storage device 2a2. The processor 2a1 may include a central processing unit (CPU). The storage device 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN) or the like.

[Configuration of Component Replacement Device 50]

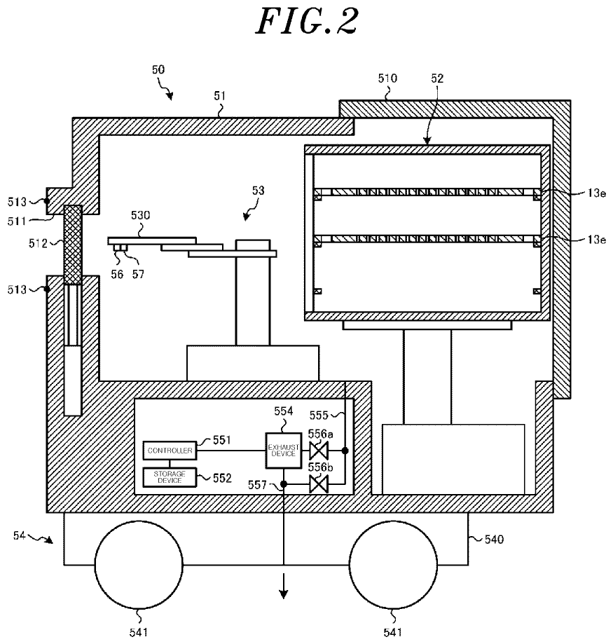

FIG. 2 is a schematic cross-sectional view showing an example of the component replacement device 50 in the first embodiment. The component replacement device 50 includes a container 51, a cassette 52, a transfer arm 53, and a moving mechanism 54. The container 51 has an opening 511 connected to the plasma processing chamber 10, a gate valve 512 for opening/closing the opening 511, and a lid 510. A sealing member 513 such as an O-ring or the like is disposed around the opening 511. The lid 510 is opened and closed when the cassette 52 is replaced. The container 51 accommodates the cassette 52 and the transfer arm 53.

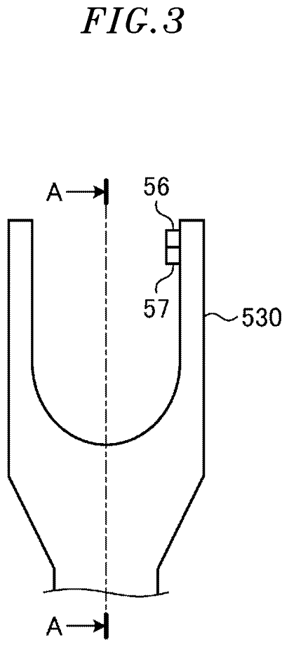

The cassette 52 accommodates unused components and used components that have been replaced with unused components. In the present embodiment, the component is, for example, the upper electrode 13e. The transfer arm 53 has an end effector at the tip end thereof. In the present embodiment, the end effector 530 is provided with a distance sensor 56 and a camera 57, as shown in FIG. 3, for example. FIG. 3 is a plan view showing an example of the end effector 530 in the first embodiment. The A-A cross section of FIG. 3 corresponds to FIG. 2. In the present embodiment, the distance sensor 56 and the camera 57 disposed at the end effector 530 are used to position the end effector 530 with respect to the plasma processing chamber 10. The positioning will be described in detail later.

The transfer arm 53 uses the end effector 530 to take out the upper electrode 13e that has not been used from the cassette 52. Further, the transfer arm 53 removes the used upper electrode 13e from the plasma processing chamber 10 and accommodates the removed upper electrode 13e in the cassette 52. Then, the transfer arm 53 takes out an unused upper electrode 13e from the cassette 52 and loads the upper electrode 13e into the plasma processing chamber 10 through the opening 511. The upper electrode 13e loaded into the plasma processing chamber 10 is installed at the bottom surface of the electrode support 13d.

Two transfer arms 53 may be disposed in the container 51, so that one transfer arm 53 may unload a used component from the plasma processing chamber 10, and the other transfer arm 53 may load an unused component into the plasma processing chamber 10. Alternatively, two end effectors 530 may be disposed at the transfer arm 53. In this case, one end effector 530 unloads a used component from the plasma processing chamber 10 and the other end effector 530 loads an unused component into the plasma processing chamber 10. Accordingly, it is possible to prevent reaction by-products peeled off from the used component from being adhered to the unused component.

Further, in the case of accommodating the used component unloaded from the plasma processing chamber 10 into the cassette 52, the transfer arm 53 accommodates the used component below the unused component accommodated in the cassette 52. Accordingly, it is possible to prevent reaction by-products or the like from falling from the used component and being adhered to the unused component in the cassette 52.

Further, in the cassette 52, a space for accommodating components may be partitioned for each component to be accommodated. Accordingly, regardless of the accommodating position of the used component in the cassette 52, the unused component can be prevented from being contaminated by reaction by-products peeled off from the used component.

The moving mechanism 54 has a main body 540 and wheels 541. In the present embodiment, the component replacement device 50 does not have a power source. Therefore, the component replacement device 50 is moved to the position of the plasma processing chamber 10 by a user or the like. In another embodiment, a power supply such as a battery, a power source, a steering mechanism, and the like are disposed in the main body 540, and the component replacement device 50 may autonomously move to the position of the plasma processing chamber 10.

The component replacement device 50 includes a controller 551, a storage device 552, and an exhaust device 554. The exhaust device 554 is connected to the space in the container 51 through a valve 556a and a line 555. The exhaust device 554 performs suction of a gas in the space in the container 51 through the valve 556a and the line 555, and discharges the gas to the outside of the component replacement device 50 through an exhaust port 557. Accordingly, the container 51 can be depressurized to a predetermined vacuum level, and moisture or the like adhered to the unused component can be reduced. Further, the pressure in the container 51 may be lower than the pressure in the plasma processing chamber 10. Hence, when the component replacement device 50 is connected to the plasma processing chamber 10 and the gate valve 512 is opened, a gas can flow from the plasma processing chamber 10 into the container 51. Therefore, particles in the container 51 can be prevented from entering the plasma processing chamber 10.

Further, the line 555 is connected to the exhaust port 557 through a valve 556b. For example, in the case of replacing the cassette 52, the valve 556b is opened and the pressure in the space in the container 51 is returned to the atmospheric pressure.

The storage unit 552 such as a ROM, an HDD, an SSD, or the like, stores data, programs, or the like used by the controller 551. The controller 551 is a processor such as a CPU, a digital signal processor (DSP), or the like, for example, and controls individual components of the component replacement device 50 by reading and executing the program in the storage device 552.

[Component Replacement Method]

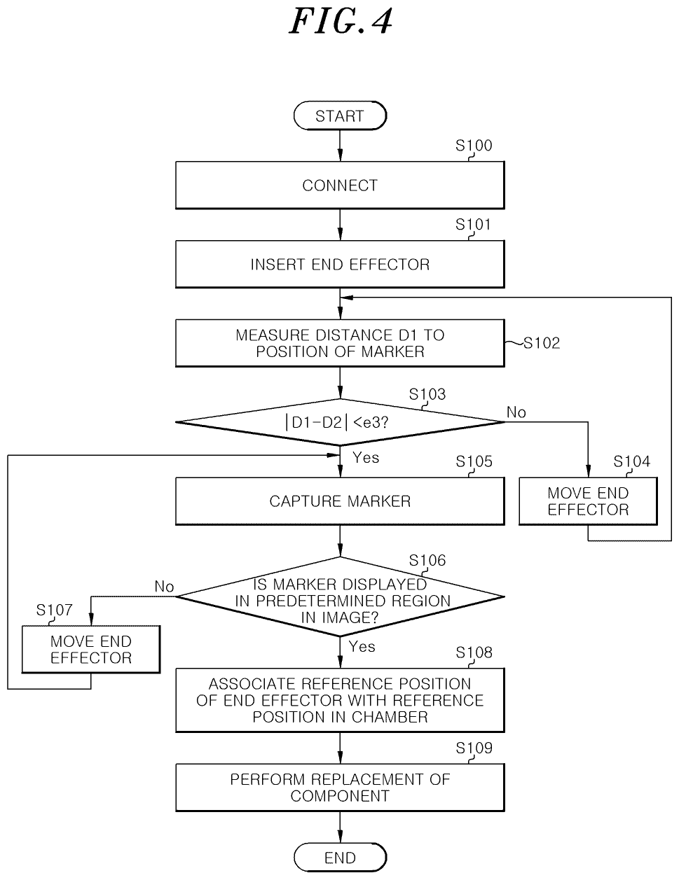

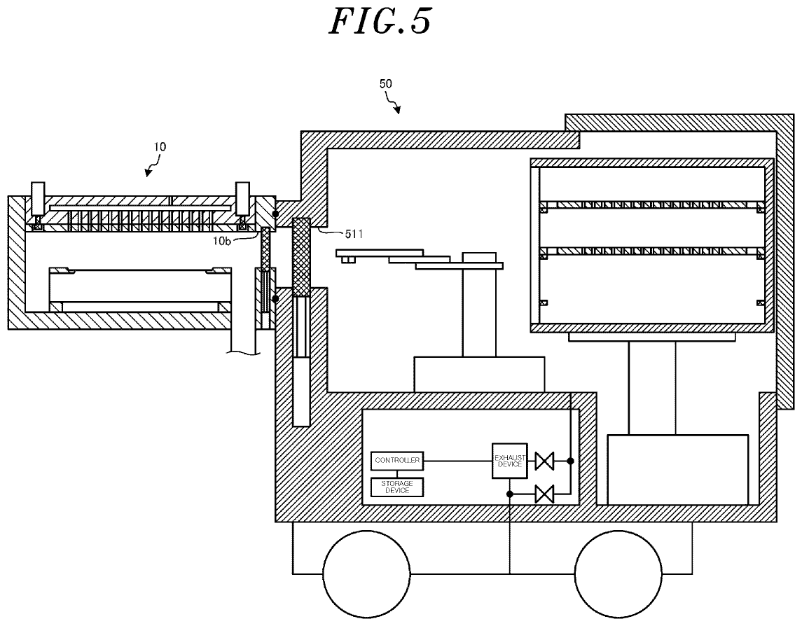

FIG. 4 is a flowchart showing an example of a component replacement method in the first embodiment. Hereinafter, an example of the component replacement method will be described with reference to FIGS. 5 to 15.

First, the component replacement device 50 moves to the position of the plasma processing chamber 10, and the component replacement device 50 and the plasma processing chamber 10 are connected (step S100). Step S100 is an example of step a). In step S100, as shown in FIG. 5, for example, the opening 10b of the plasma processing chamber 10 and the opening 511 of the component replacement device 50 are connected.

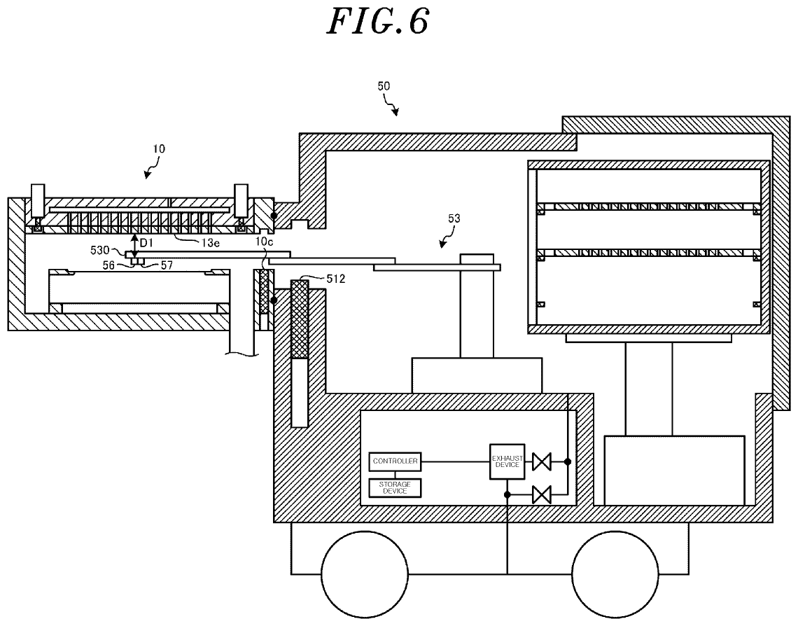

Next, the controller 551 controls the transfer arm 53 of the component replacement device 50 to insert the end effector 530 into the plasma processing chamber 10 (step S101). In step S101, the gate valve 10c and the gate valve 512 are opened as shown in FIG. 6, for example. Then, the transfer arm 53 extends into the plasma processing chamber 10, and the end effector 530 is inserted into the plasma processing chamber 10.

Next, the distance sensor 56 is controlled by the controller 551, and a distance D1 from the end effector 530 to the position of the marker attached to the bottom surface of the upper electrode 13e is measured (step S102). Step S102 is an example of step b). The distance D1 is an example of the first distance. In the present embodiment, the position of the marker is an example of a predetermined position in the plasma processing chamber 10.

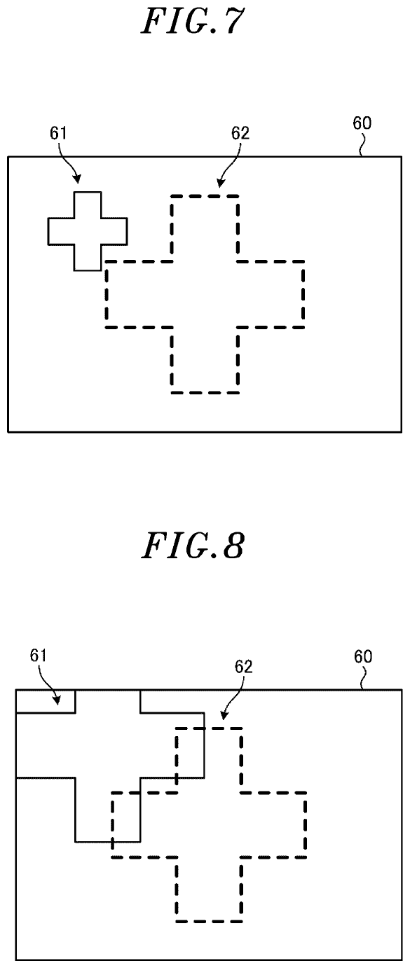

Next, the controller 551 determines whether or not the difference between the distance D1 measured in step S102 and a predetermined distance D2 is less than a predetermined distance e3 (step S103). The distance D2 is an example of the second distance, and the distance e3 is an example of a third distance. The predetermined distance e3 is, for example, 0.5 mm. When the difference between the distance D1 and the distance D2 is greater than or equal to the distance e3 (NO in S103), the controller 551 controls the transfer arm 53 of the component replacement device 50 until the difference between the distance D1 and the distance D2 becomes small, and the end effector 530 is moved (step S104). Step S104 is an example of step c). Then, the processing of step S102 is executed again. For example, when the distance D1 is greater than the distance D2, if the bottom surface of the upper electrode 13e is captured by the camera 57, the marker 61 in an image 60 captured by the camera 57 is displayed smaller than a region 62 as shown in FIG. 7, for example.

On the other hand, when the difference between the distance D1 and the distance D2 is less than the distance e3 (YES in step S103), the camera 57 is controlled by the controller 551 to capture the marker attached to the bottom surface of the upper electrode 13e (step S105). Step S105 is an example of step d). In step S105, the image 60 is captured as shown in FIG. 8, for example. When the difference between the distance D1 and the distance D2 is less than the distance e3, the marker 61 attached to the bottom surface of the upper electrode 13e is displayed in substantially the same size as that of the predetermined region 62, as illustrated in the image 60 of FIG. 8, for example.

Next, the controller 551 determines whether or not the marker 61 attached to the bottom surface of the upper electrode 13e is displayed in the predetermined region 62 of the image 60 captured in step S105 (step S106). When the marker 61 is not displayed in the region 62 of the image 60 (NO in step S106), the controller 551 controls the transfer arm 53 of the component replacement device 50 so that the marker 61 in the image 60 becomes close to the region 62, and the end effector 530 is moved (step S107). Step S107 is an example of step e). Then, the processing of step S105 is executed again.

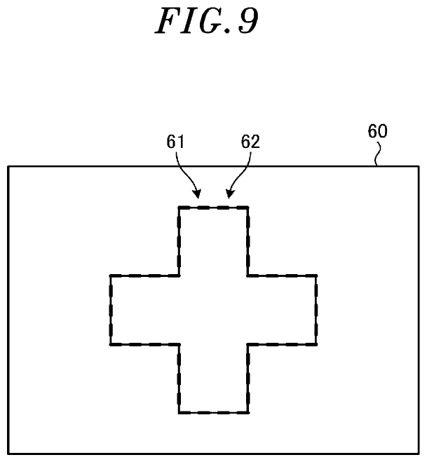

For example, as shown in FIG. 9, when the marker 61 is displayed in the region 62 of the image 60 (YES in step S106), the controller 551 associates the reference position of the end effector 530 with the reference position in the plasma processing chamber 10 (step S108). Accordingly, the coordinate system for the transfer arm 53 is associated with the coordinate system in the plasma processing chamber 10, and the positioning of the end effector 530 with respect to the plasma processing chamber 10 is completed. Thereafter, the component is replaced by the end effector with reference to the position of the end effector 530 in a state where the marker 61 is displayed in the region 62 of the image 60 (step S109). Step S109 is an example of step f). Then, the processing shown in this flowchart is terminated.

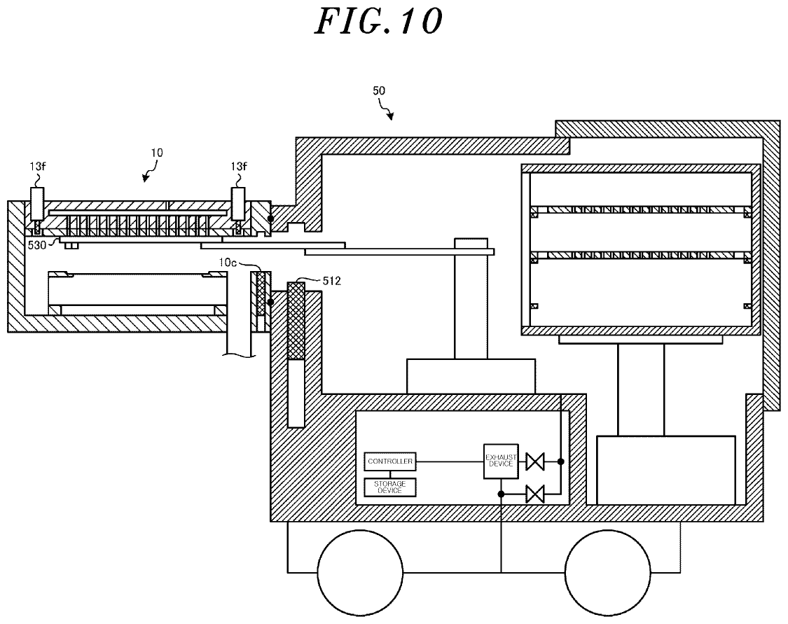

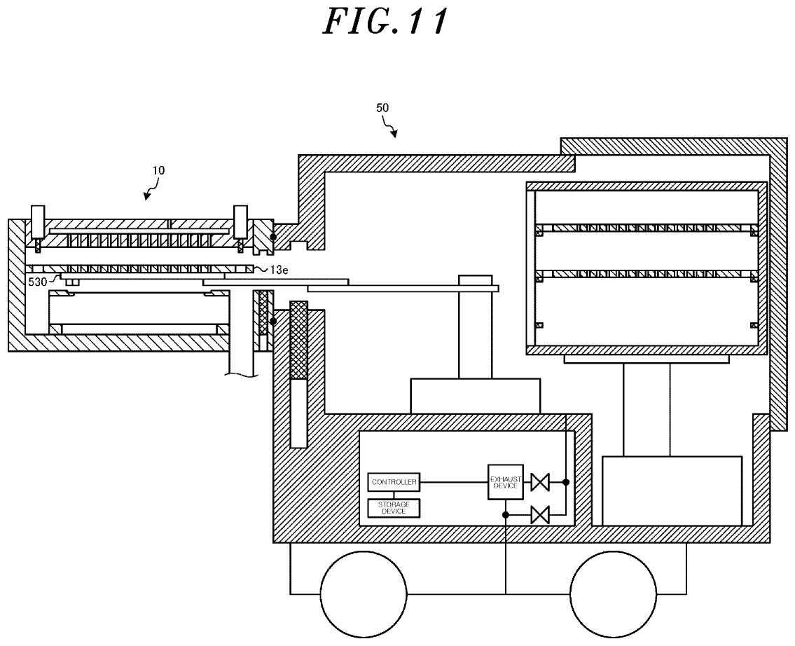

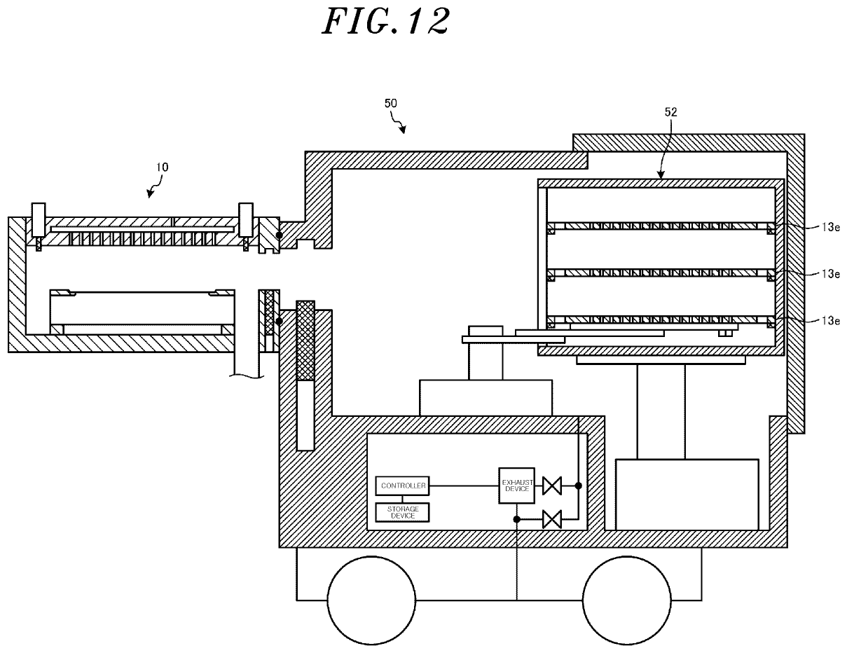

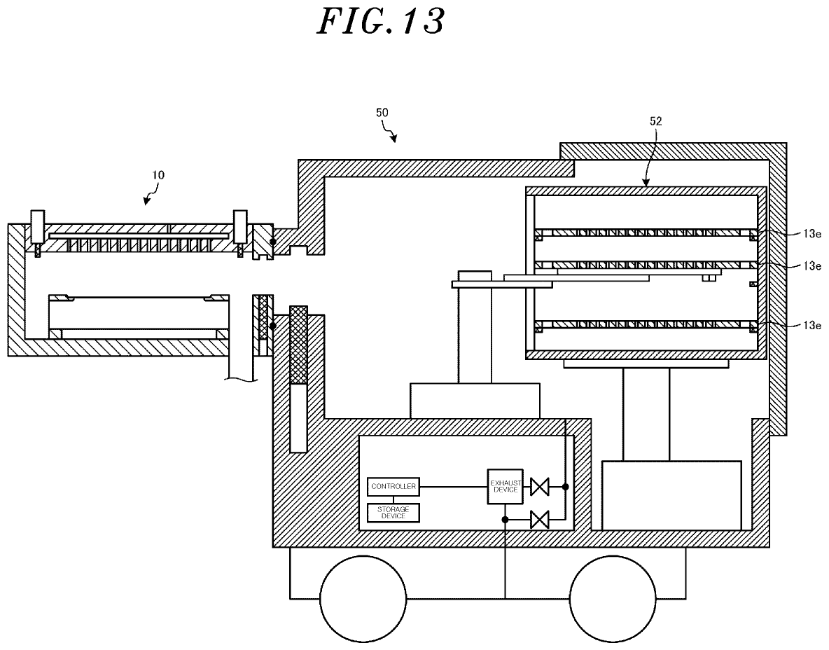

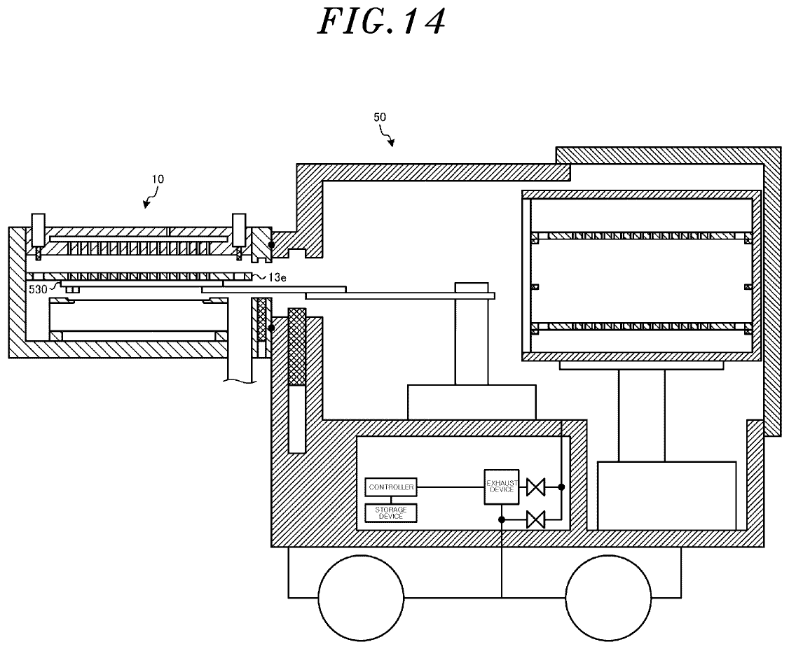

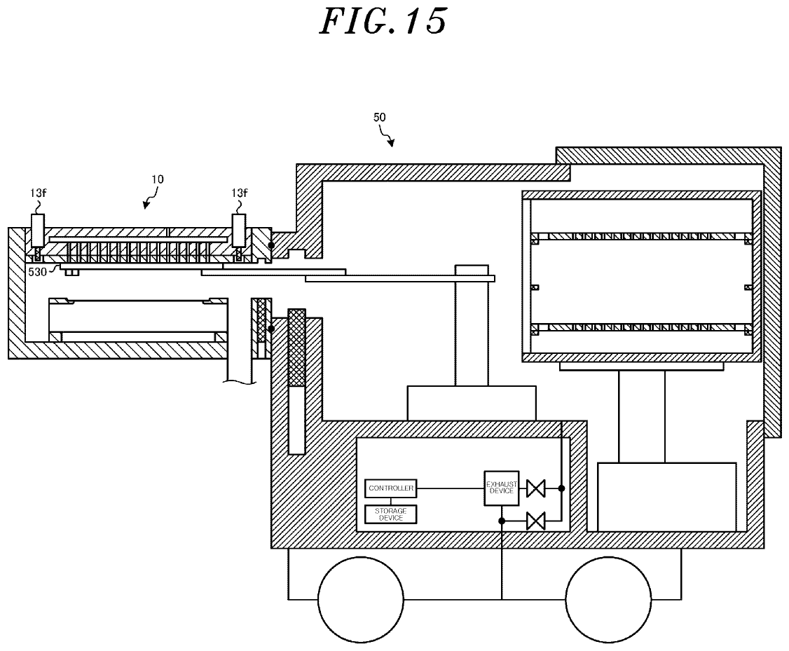

In step S108, as shown in FIG. 10, for example, the end effector 530 is lifted, and the used upper electrode 13e is supported by the end effector 530. Next, the holding mechanism 13f is controlled by the controller 2, and the fixing of the used upper electrode 13e is released. Accordingly, the used upper electrode 13e is placed on the end effector 530. Then, as shown in FIG. 11, for example, the end effector 530 is lowered. Then, as shown in FIG. 12, for example, the used upper electrode 13e is accommodated in the cassette 52. Then, as shown in FIG. 13, for example, an unused upper electrode 13e is taken out from the cassette 52. Then, as shown in FIG. 14, for example, the unused upper electrode 13e is inserted into the plasma processing chamber 10. Then, as shown in FIG. 15, for example, the end effector is lifted and the holding mechanism 13f is controlled by the controller 2, so that the unused upper electrode 13e is fixed to the bottom surface of the electrode support 13d.

The reaction by-products (so-called deposits) may be adhered to the inner portion of the plasma processing chamber after the processing of the substrate W. Therefore, it is preferable to clean the inside of the plasma processing chamber 10 using plasma or the like before the used component in the plasma processing chamber 10 is removed. The step of performing cleaning is an example of step g). Accordingly, the accuracy of the positioning of the end effector 530 with respect to the plasma processing chamber 10 can be improved. In addition, it is possible to suppress scattering of deposits peeled off from a used component in the plasma processing chamber 10 in the case of replacing a component in the plasma processing chamber 10.

Depending on the positional relationship between the predetermined position in the plasma processing chamber 10 and the end effector 530, the distance to the predetermined position in the plasma processing chamber 10 may change by moving the end effector 530 in step S107. Therefore, it is preferable to further perform the processing of steps S102 to S106 at least once before the processing of step S108 is executed. Accordingly, the accuracy of the positioning of the end effector 530 with respect to the plasma processing chamber 10 can be improved.

The first embodiment has been described above. As described above, in the present embodiment, the component replacement method includes steps a), b), c), d), e), and f). In step a), the component replacement device 50 is connected to the plasma processing chamber 10 of the plasma processing system 100 for processing the substrate W. In step b), the end effector 530 disposed at the tip end of the transfer arm in the component replacement device 50 is inserted into the plasma processing chamber 10, and the distance D1 from a predetermined position in the plasma processing chamber 10 to the end effector 530 is measured using the distance sensor 56 disposed at the end effector 530. In step c), the end effector is moved until the difference between the distance D1 and the predetermined distance D2 becomes less than the predetermined distance e3. In step d), the marker installed at the predetermined position in the plasma processing chamber is captured by the camera 57 disposed at the end effector 530. In step e) the end effector 530 is moved so that the marker can be captured at a predetermined position in the image 60 captured by the camera 57. In step f), the component in the plasma processing chamber 10 is replaced using the end effector 530 with reference to the position of the end effector 530 in a state where the marker is captured in the predetermined position in the image 60 captured by the camera 57. Accordingly, the component in the plasma processing chamber 10 can be replaced after the transfer arm 53 is accurately positioned with respect to the plasma processing chamber 10.

The component replacement method in the above-described embodiment further includes step g) of cleaning the plasma processing chamber 10. Step g) is preferably executed further before step b). Accordingly, the accuracy of the positioning of the end effector 530 with respect to the plasma processing chamber 10 can be improved. Further, it is possible to suppress scattering of deposits peeled off from the used component in the plasma processing chamber 10 in the case of replacing the component in the plasma processing chamber 10. In the component replacement method of the above-described embodiment, steps b) to e) are further executed in that order at least once before step f). Accordingly, the accuracy of the positioning of the end effector 530 with respect to the plasma processing chamber 10 can be improved.

Further, the component replacement device 50 in the above embodiment includes the container 51, the transfer arm disposed in the container 51 and having the end effector 530, and the controller 551. The end effector 530 is provided with the distance sensor 56 and the camera 57. The controller executes steps a), b), c), d), e), and f). In step a), the container 51 is connected to the plasma processing chamber of the plasma processing system 100 for processing the substrate W. In step b), the end effector 530 is inserted into the plasma processing chamber 10, and the distance D1 from the predetermined position in the plasma processing chamber 10 to the end effector 530 is measured using the distance sensor 56. In step c), the end effector 530 is moved until the difference between the distance D1 and the predetermined distance D2 becomes less than the predetermined distance e3. In step d), the camera 57 is used to capture the marker installed at the predetermined position in the plasma processing chamber 10. In step e), the end effector is moved so that the marker is captured at the predetermined position in the image 60 captured by the camera 57. In step f), the component in the plasma processing chamber 10 is replaced using the end effector 530 with reference to the position of the end effector 530 in a state where the marker is captured in the predetermined position in the image 60 captured by the camera 57. Accordingly, the component in the plasma processing chamber 10 can be replaced after the transfer arm 53 is accurately positioned with respect to the plasma processing chamber 10.

### Second Embodiment

The surface of the component in the plasma processing chamber 10 may be consumed when the substrate W is processed or the plasma processing chamber 10 is cleaned. Therefore, if the end effector 530 is positioned with reference to the position of the surface of the consumed component, the accuracy of the positioning of the end effector 530 with respect to the plasma processing chamber 10 may be degraded. Especially, in the case of installing an unused component, it is preferable to ensure high accuracy of the positioning of the end effector 530 with respect to the plasma processing chamber 10. In the case of removing the used component, if the removed component can be accommodated in the cassette 52, the high accuracy of the positioning of the end effector 530 with respect to the plasma processing chamber 10 may not be required.

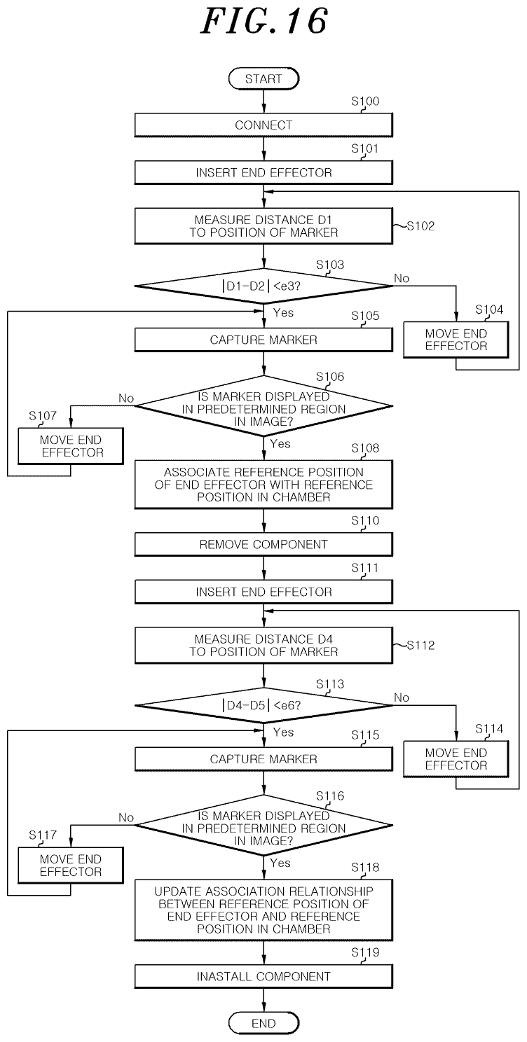

Therefore, in the present embodiment, after a used component is removed and before an unused component is installed, the end effector is further positioned with respect to the plasma processing chamber 10 with reference to the installation position of the unused component. Accordingly, the assembly error of the unused component can be reduced. Hereinafter, a component replacement method in the second embodiment will be described below with reference to FIG. 16. The configurations of the plasma processing chamber 10 and the component replacement device 50 are the same as those of the plasma processing chamber 10 and the component replacement device 50 described in the first embodiment, so that redundant description will be omitted.

[Component Replacement Method]

FIG. 16 is a flowchart showing an example of the component replacement method according to the second embodiment. In FIG. 16, the steps having the same step numbers in FIG. 4 are the same as those described in FIG. 4 except the following differences, so that the description thereof will be omitted.

In step S108, after the controller 551 associates the reference position of the end effector 530 with the reference position in the plasma processing chamber 10, the component is removed by the end effector 530 (step S110). The processing performed after step S110 is an example of the processing included in step f). Step S110 is an example of step f1).

Next, the transfer arm 53 of the component replacement device 50 is controlled by the controller 551, and the end effector 530 enters the plasma processing chamber 10 again (step S111). Then, the distance sensor 56 is controlled by the controller 551 to measure a distance D4 from the end effector 530 to the position of the marker installed on the bottom surface of the electrode support 13d where the upper electrode 13e is attached (step S112). Step S112 is an example of step f2). The distance D4 is an example of a fourth distance. In the present embodiment, the position of the marker is an example of the installation position of an unused component in the plasma processing chamber 10.

Next, the controller 551 determines whether or not the difference between the distance D4 measured in step S112 and the predetermined distance D5 is less than a predetermined distance e6 (step S113). The distance D5 is an example of a fifth distance, and the distance e6 is an example of a sixth distance. The predetermined distance e6 is, for example, 0.5 mm. When the difference between the distance D4 and the distance D5 is greater than or equal to the distance e6 (NO in step S113), the controller 551 controls the transfer arm 53 of the component replacement device 50 to reduce the difference between the distance D4 and the distance D5, and the end effector 530 is moved (step S114). Step S114 is an example of step f3). Then, the processing of step S112 is executed again.

On the other hand, when the difference between the distance D4 and the distance D5 is less than the distance e6 (YES in step S113), the camera 57 is controlled by the controller 551 to capture the marker attached to the bottom surface of the electrode support 13d (step S115). Step S115 is an example of step f4). Then, the controller 551 determines whether or not the marker attached to the bottom surface of the electrode support 13d is displayed in the predetermined region in the image captured in step S115 (step S116). When the marker is not displayed in the predetermined region in the image (NO in step S116), the controller 551 controls the transfer arm 53 of the component replacement device 50 so that the marker in the image becomes close to the predetermined region in the image. Accordingly, the end effector 530 is moved (step S117). Step S117 is an example of step f5). Then, the processing of step S115 is executed again.

When the marker is displayed in the predetermined region in the image (YES in step S116), the controller 551 updates the association relationship between the reference position of the end effector 530 and the reference position in the plasma processing chamber 10 (step S118). Accordingly, the positioning of the end effector 530 with respect to the plasma processing chamber 10 with reference to the installation surface of the unused component is completed. Next, the component is installed by the end effector 530 (step S119). Step S119 is an example of step f6). Then, the processing shown in this flowchart is terminated.

The second embodiment has been described above. As described above, step f) in the component replacement method of the present embodiment includes steps f1), f2), f3), f4), f5), and f6). In step f1), the used component is removed by the end effector 530. In step f2), the distance D4 from the installation position of the unused component in the plasma processing chamber 10 to the end effector 530 is measured using the distance sensor 56. In step f3), the end effector is moved until difference between the distance D4 and the predetermined distance D5 becomes less than the predetermined distance e6. In step f4), the marker installed at the installation position is captured using the distance sensor 56. In step f5), the end effector 530 is moved so that the marker is captured at a predetermined position in the image captured by the distance sensor 56 camera. In step f6), the unused component is installed at the installation position using the end effector 530 with reference to the position of the end effector 530 in a state where the marker is captured in the predetermined position in the image captured by the distance sensor 56. Accordingly, the assembly error of the unused component can be reduced.

Further, when the used component is removed, deposits may be adhered to the installation surface of the unused component. If the unused component is installed with the deposits attached, the deposits may be interposed between the unused component and the installation surface of the unused component, which may cause misalignment of the installation position of the unused component. Therefore, it is preferable to clean the plasma processing chamber 10 using plasma or the like after the used component is removed in step S110 and before the unused component is installed in step S119. The step of performing cleaning is an example of step g). Accordingly, the assembling error of the unused component can be further reduced.

### Third Embodiment

In the first and second embodiments described above, the end effector 530 is positioned with respect to the plasma processing chamber 10 using the distance sensor 56 and the camera 57 disposed at the end effector 530. On the other hand, in the present embodiment, the end effector 530 is positioned with respect to the plasma processing chamber 10 using the distance sensor 56 and the camera 57 disposed at the plasma processing chamber 10. In the following description, the differences from the first embodiment will be mainly described.

[Configuration of Component Replacement System 700]

FIG. 17 is a system configuration diagram showing an example of a component replacement system 700 in the third embodiment. The component replacement system 700 includes a control device 70, the plasma processing system 100, and the component replacement device 50. The control device 70 and the plasma processing system 100 communicate with each other through a communication line such as a LAN or the like. Further, the control device 70 and the component replacement device 50 communicate wirelessly. The control device 70 and the plasma processing system 100 may communicate wirelessly.

[Configuration of Control Device 70]

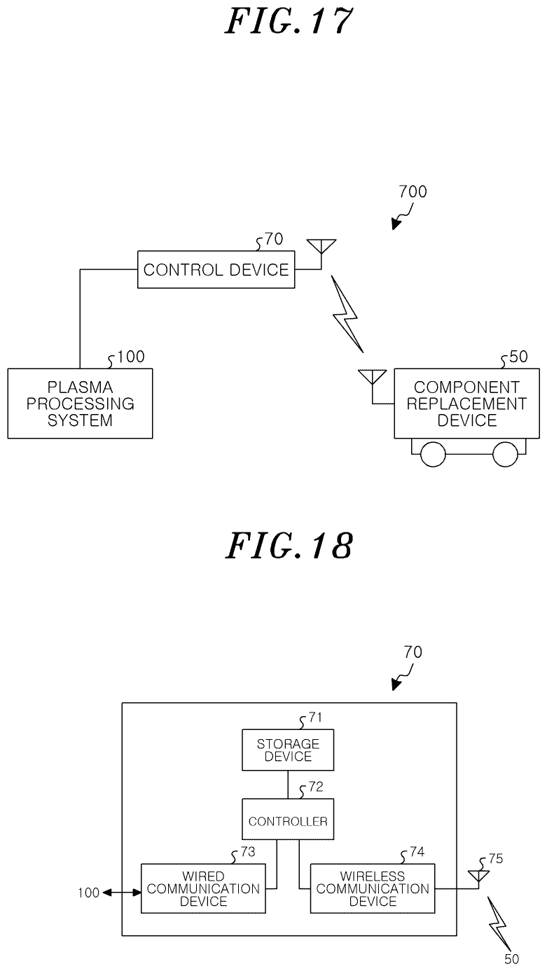

FIG. 18 is a block diagram showing an example of the control device 70. The control device 70 includes a storage device 71, a controller 72, a wired communication device 73, and a wireless communication device 74. The controller 72 performs various controls based on programs, data, and the like stored in the storage device 71. The controller 72 includes a CPU. The storage device 71 includes a RAM, a ROM, an HDD, an SSD, or a combination thereof. The wired communication device 73 communicates with the plasma processing system 100 through a communication line such as a LAN or the like. The wireless communication device 74 communicates with the component replacement device 50 through an antenna 75.

[Configuration of Plasma Processing System 100]

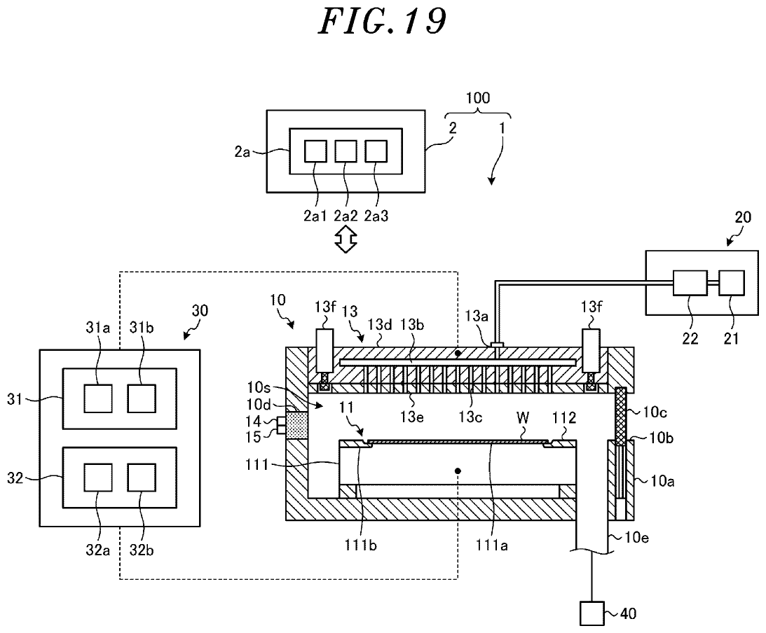

FIG. 19 is a system configuration diagram showing an example of the plasma processing system 100 in the third embodiment. In FIG. 19, the components designated by like reference numerals in FIG. 1 have the same or similar functions as those of the components in FIG. 1 except the following differences, so that the description thereof will be omitted.

A window 10d made of a light-transmitting material such as quartz or the like is disposed on the sidewall 10a of the plasma processing chamber 10. The distance sensor 14 and the camera 15 are provided outside the plasma processing chamber near the window 10d.

[Configuration of Component Replacement Device 50]

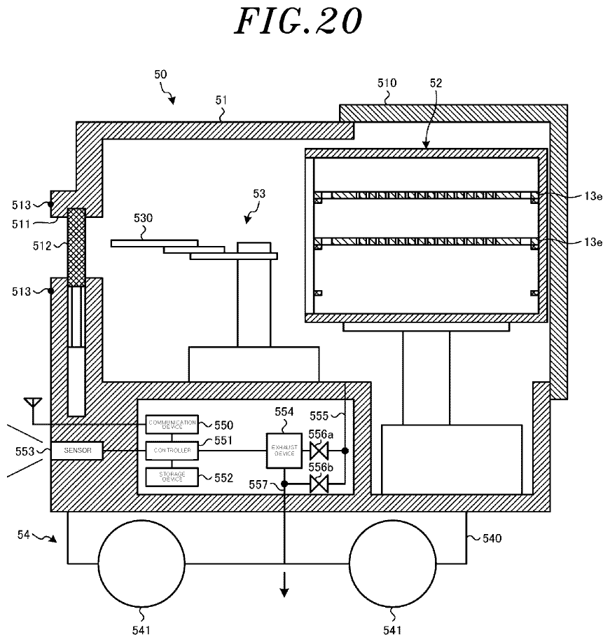

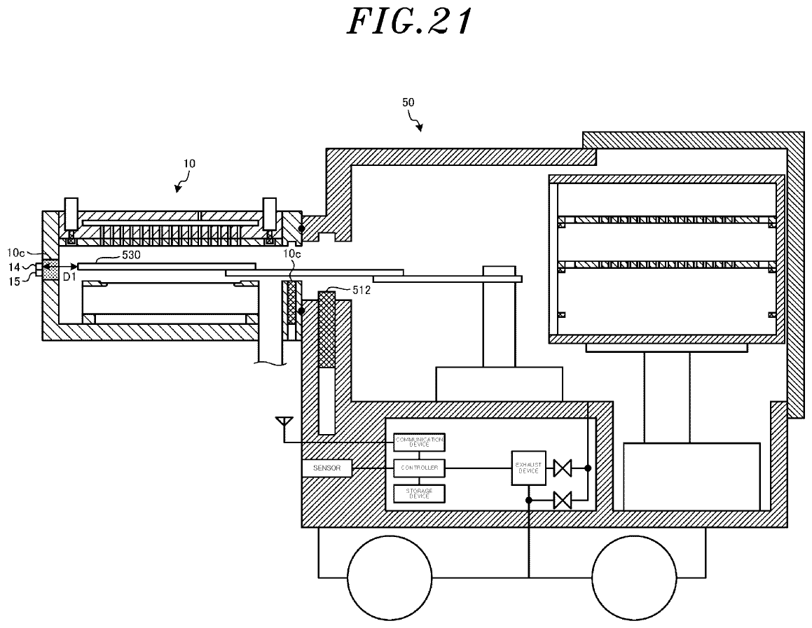

FIG. 20 is a schematic cross-sectional view showing an example of the component replacement device 50 in the third embodiment. In FIG. 20, the components designated by like reference numerals in FIG. 2 have the same or similar functions as those of the components in FIG. 2 except the following differences, so that the description thereof will be omitted.

The component replacement device 50 includes a communication device 550 and a sensor 553. The communication device 550 is, for example, a wireless communication circuit, and performs wireless communication with the control device 70. The sensor 553 senses the vicinity of the component replacement device 50 and outputs the sensing result to the controller 551. In the present embodiment, the sensor 553 is, for example, an image sensor, and captures an image of the vicinity of the component replacement device 50 and outputs it to the controller 551.

In the present embodiment, the main body 540 has therein a power supply such as a battery, a power source, a steering mechanism, and the like. The wheels 541 are rotated by the power source in the main body 540, and moves the component replacement device 50 in the direction controlled by the steering mechanism in the main body 540. Further, the controller 551 controls the moving mechanism 54 using the sensing result of the sensor 553, for example, to move the component replacement device 50 to the position of the plasma processing chamber 10. The component replacement device 50 may be moved to the position of the plasma processing chamber by a user or the like without a power source.

[Component Replacement Method]

The component replacement method in the present embodiment has the same sequence as that shown in FIG. 4. Therefore, hereinafter, the component replacement method of the present embodiment will be described with reference to FIG. 4. In the present embodiment, first, the component replacement device 50 is moved to the position of the plasma processing chamber 10, and the component replacement device and the plasma processing chamber 10 are connected (step S100). Step S100 is an example of step a). Then, the transfer arm 53 of the component replacement device 50 is controlled by the controller 551, and the end effector 530 is inserted into the plasma processing chamber 10 (step S101).

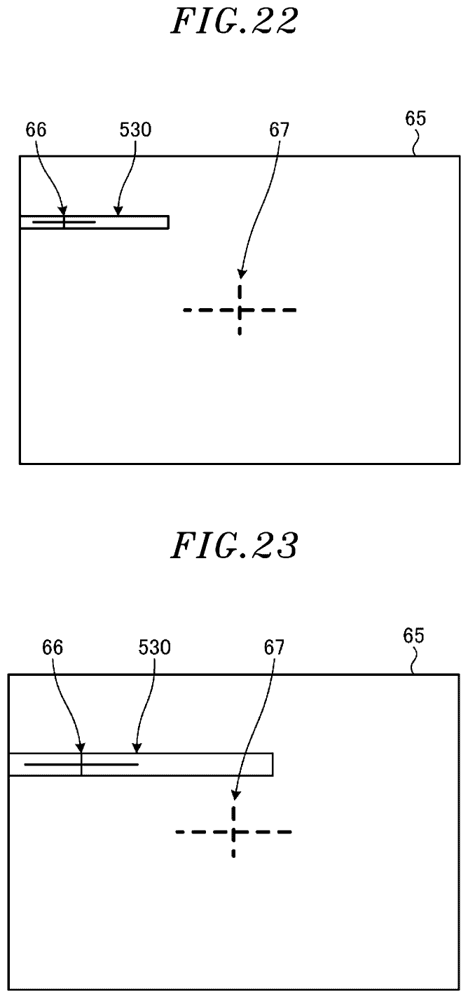

Next, the controller 2 of the plasma processing system controls the distance sensor 14 to measure the distance D1 from the predetermined position in the plasma processing chamber 10 to the tip end of the end effector 530 (step S102). Step S102 is an example of step b). The distance D1 is an example of the first distance. The controller 2 determines whether or not the difference between the distance D1 measured in step S102 and the predetermined distance D2 is less than the predetermined distance e3 (step S103). The distance D2 is an example of the second distance, and the distance e3 is an example of the third distance. The predetermined distance e3 is, for example, 0.5 mm. When the difference between the distance D1 measured in step S102 and the predetermined distance D2 is greater than or equal to the predetermined distance e3, if the tip end of the end effector 530 is captured by the camera 15, an image 65 shown in FIG. 22, for example, is captured. A marker 66 is attached to the tip end of the end effector 530.

When the difference between the distance D1 and the distance D2 is greater than or equal to the distance e3 (NO in step S103), the controller 2 of the plasma processing system 100 transmits the difference between the distance D1 and the distance D2 and the information on a larger distance to the control device 70. The control device 70 transfers the information received from controller 2 to component replacement device 50. The controller 551 of the component replacement device 50 controls the transfer arm 53 to reduce the difference between the distance D1 and the distance D2 based on the information transmitted from the control device 70, and moves the end effector 530 (step S104). Step S104 is an example of step c). Then, the processing of step S102 is executed again.

On the other hand, when the difference between the distance D1 and the distance D2 is less than the distance e3 (YES in step S103), the camera 15 is controlled by the controller 2 of the plasma processing system 100 to capture the marker 66 installed at the tip end of the end effector (step S105). Step S105 is an example of step d). In step S105, the image 65 as shown in FIG. 23, for example, is captured.

Next, the controller 2 of the plasma processing system determines whether or not the marker 66 installed at the tip end of the end effector 530 is displayed at a predetermined position 67 in the image 65 captured in step S105 (step S106). When the marker 66 is not displayed at the position 67 in the image 60 (NO in step S106), the position of the end effector 530 is changed so that the marker 66 is displayed at the position 67 in the image 65. For example, the controller 2 of the plasma processing system 100 transmits the information indicating the direction from the position of the marker 66 to the position 67 in the image 65 to the control device 70. The control device 70 transmits the information received from the controller 2 to the component replacement device 50. The controller 551 of the component replacement device 50 controls the transfer arm 53 so that the position of the marker 66 becomes close to the position 67 in the image based on the information transferred from the control device 70, and moves the end effector 530 (step S107). Step S107 is an example of step e). Then, the processing of step S105 is executed again.

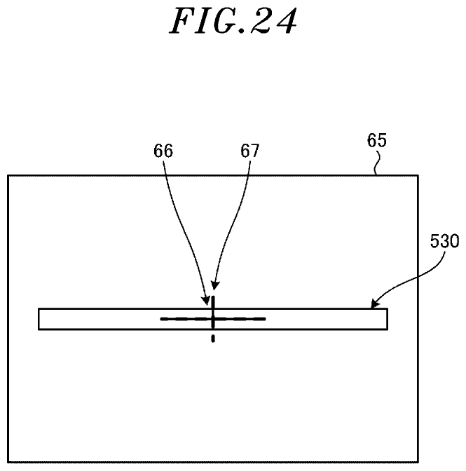

For example, as shown in FIG. 24, when the marker 66 is displayed at the position 67 in the image 65 (YES in step S106: Yes), the information indicating that the marker 66 is displayed at the position 67 in the image 65 is transmitted from the controller 2 of the plasma processing system 100 to the control device 70. The control device 70 transmits the information received from the controller 2 to the component replacement device 50. The controller 551 of the component replacement device 50 associates the reference position of the end effector 530 with the reference position in the plasma processing chamber 10 based on the information transmitted from the control device 70 (step S108). Accordingly, the positioning of the end effector 530 with respect to the plasma processing chamber 10 is completed. Then, the component is replaced by the end effector 530 with reference to the position of the end effector 530 in a state where the marker is displayed at the position 67 in the image 65 (step S109). Step S109 is an example of step f). Then, the processing shown in this flowchart of FIG. 4 is terminated.

The third embodiment has been described above. As described above, in the present embodiment, the component replacement method includes steps a), b), c), d), e), and f). In step a), the component replacement device 50 is connected to the plasma processing chamber 10 of the plasma processing system 100 for processing the substrate W. In step b), the end effector 530 disposed at the tip end of the transfer arm in the component replacement device 50 is inserted into the plasma processing chamber 10, and the distance D1 from the predetermined position in the plasma processing chamber to the end effector 530 is measured using the distance sensor 14 disposed at the plasma processing chamber 10. In step c), the end effector 530 is moved until the difference between the distance D1 and the predetermined distance D2 becomes less than the predetermined distance e3. In step d), the marker installed at the end effector 530 is captured by the camera 15 disposed at the plasma processing chamber 10. In step e), the end effector 530 is moved so that the marker is captured at the predetermined position in the image 65 captured by the camera 15. In step f), the component in the plasma processing chamber 10 is replaced using the end effector 530 with reference to the position of the end effector 530 in a state where the marker is captured in the predetermined position in the image 65 captured by the camera 15. Accordingly, the component in the plasma processing chamber 10 can be replaced after the transfer arm 53 is accurately positioned with respect to the plasma processing chamber 10.

Further, the component replacement system 700 in the above-described embodiment includes the plasma processing system 100 for processing the substrate W, the component replacement device 50 for replacing a component in the plasma processing system 100, and the control device 70 for controlling the plasma processing system 100 and the component replacement device 50. The plasma processing system 100 includes the plasma processing chamber 10 where components are installed, the distance sensor 14 disposed at the plasma processing chamber 10, and the camera 15 disposed at the plasma processing chamber 10. The component replacement device 50 includes the container 51, and the transfer arm 53 disposed in the container 51 and having the end effector 530 at the tip end thereof. The control device 70 executes steps a), b), c), d), e), and f). In step a), the component replacement device 50 is connected to the plasma processing chamber 10. In step b), the end effector 530 is inserted into the plasma processing chamber 10, and the distance D1 from the predetermined position in the plasma processing chamber to the end effector 530 is measured using the distance sensor 14. In step c), the end effector 530 is moved until the difference between the distance D1 and the predetermined distance D2 becomes less than the predetermined distance e3. In step d), the marker installed at the end effector 530 is captured by the camera 15. In step e), the end effector 530 is moved so that the marker is captured at the predetermined position in the image 65 captured by the camera 15. In step f), the component in the plasma processing chamber 10 is replaced using the end effector 530 with reference to the position of the end effector 530 in a state where the marker is captured in the predetermined position in the image 65 captured by the camera 15. Accordingly, the component in the plasma processing chamber 10 can be replaced after the transfer arm 53 is accurately positioned with respect to the plasma processing chamber 10.

When the used component is removed, deposits may be adhered to the installation surface of the unused component. If the unused component is installed with the deposits attached, the deposits may be interposed between the unused component and the installation surface of the unused component, which may cause misalignment of the installation position of the unused component. Therefore, in step S109, it is preferable to clean the plasma processing chamber 10 using plasma or the like after the used component is removed and before the unused component is installed. The step of performing cleaning is an example of step g). Accordingly, the assembly error of the unused component can be further reduced.

### Other Applications

The technique of the present disclosure is not limited to the above-described embodiments, and various modifications can be made within the scope of the gist thereof.

For example, in the above-described first and second embodiments, the markers attached to the bottom surface of the electrode support 13d and the bottom surface of the upper electrode 13e have been used as an example of features captured in the predetermined positions in the plasma processing chamber 10. However, the present disclosure is not limited thereto. Other structural shapes may be used as long as the feature of the predetermined position in the plasma processing chamber 10 indicates the reference position in the plasma processing chamber 10. Other structural shapes may be, for example, the arrangement of the plurality of gas inlet ports 13c disposed at the shower head 13, or the plurality of holes disposed at the substrate support 11 to allow lift pins to penetrate therethrough.

In the above-described first and second embodiments, the end effector 530 is provided with the distance sensor 56 and the camera 57. In the third embodiment, the plasma processing chamber 10 is provided with the distance sensor 14 and the camera 15. However, the present disclosure is not limited to thereto. In another embodiment, the end effector 530 may be provided with one of the distance sensor and the camera, and the plasma processing chamber 10 may be provided with the other one. Alternatively, each of the end effector 530 and the plasma processing chamber 10 may be provided with the distance sensor and the camera.

In the above-described embodiments, the plasma processing system 100 for performing processing using capacitively coupled plasma (CCP) has been described as an example of the plasma source. However, the plasma source is not limited thereto. The plasma source may be inductively coupled plasma (ICP), microwave excited surface wave plasma (SWP), electron cyclotron resonance plasma (ECP), helicon wave excited plasma (HWP), or the like, other than capacitively coupled plasma.

Further, it should be noted that the embodiments of the present disclosure are illustrative in all respects and are not restrictive. The above-described embodiments can be embodied in various forms. Further, the above-described embodiments may be omitted, replaced, or changed in various forms without departing from the scope of the appended claims and the gist thereof.

The following additional statements are disclosed with respect to the above embodiments.

(Additional Statement 1)

A component replacement method comprising:
a) connecting a component replacement device to a chamber of a processing device configured to process a substrate;
b) inserting an end effector disposed at a tip end of a transfer arm in the component replacement device into the chamber, and measuring a first distance from a predetermined position in the chamber to the end effector using a distance sensor provided on the end effector;
c) moving the end effector until a difference between the first distance and a predetermined second distance becomes less than a predetermined third distance;
d) capturing a feature disposed at a predetermined position in the chamber by a camera provided on the end effector;
e) moving the end effector so that the feature is captured in a predetermined position in an image captured by the camera; and
f) replacing a component in the chamber using the end effector with reference to a position of the end effector in a state where the feature is captured in the predetermined position in the image captured by the camera.

(Additional Statement 2)

The component replacement method of additional statement 1, wherein said step f) includes:
f1) removing a used component by the end effector;
f2) measuring a fourth distance from an installation position of an unused component in the chamber to the end effector using the distance sensor;
f3) moving the end effector until a difference between the fourth distance and a predetermined fifth distance becomes less than a predetermined sixth distance;
f4) capturing a feature disposed at the installation position by the camera;
f5) moving the end effector so that the feature is captured in the predetermined position in the image captured by the camera; and
f6) installing the unused component in the installation position using the end effector with reference to a position of the end effector in a state where the feature is captured in the predetermined position in the image captured by the camera.

(Additional Statement 3)

The component replacement method of additional statement 2, further comprising:
g) cleaning the chamber,
wherein said step g) is executed between said step f1) and said step f6).

(Additional Statement 4)

A component replacement method comprising:
a) connecting a component replacement device to a chamber of a processing device configured to process a substrate;
b) inserting an end effector disposed at a tip end of a transfer arm in the component replacement device into the chamber, and measuring a first distance from a predetermined position in the chamber to the end effector using a distance sensor disposed at the chamber;
c) moving the end effector until a difference between the first distance and a predetermined second distance becomes less than a predetermined third distance;
d) capturing a feature disposed at the end effector by a camera disposed at the chamber;
e) moving the end effector so that the feature is captured in a predetermined position in an image captured by the camera; and
f) replacing a component in the chamber using the end effector with reference to a position of the end effector in a state where the feature is captured in the predetermined position in the image captured by the camera.

(Additional Statement 5)

The component replacement method of additional statement 4, further comprising:
g) cleaning the chamber,
wherein said step g) is executed after a used component is removed and before an unused component is installed in said step f).

(Additional Statement 6)

The component replacement method of additional statement 3 or 4, wherein said step g) is further executed before said step b).

(Additional Statement 7)

The component replacement method of any one of additional statements 1 to 6, wherein said steps b) to e) are further executed at least once in that order before said step f).

(Additional Statement 8)

The component replacement method of any one of additional statements 1 to 7, wherein the feature is an arrangement of a plurality of gas holes through which a gas supplied into the chamber flows.

(Additional Statement 9)

A component replacement device comprising:
a container;
a transfer arm disposed in the container and having an end effector; and
a controller,
wherein the end effector is provided with a distance sensor and a camera, and
the controller executes:
a) connecting the container to a chamber of a processing device configured to process a substrate;
b) inserting the end effector into the chamber and measuring a first distance from a predetermined position in the chamber to the end effector by the distance sensor;
c) moving the end effector until a difference between the first distance and a predetermined second distance becomes less than a predetermined third distance;
d) capturing a feature disposed at a predetermined position in the chamber by the camera;
e) moving the end effector so that the feature is captured in a predetermined position in an image captured by the camera; and
f) replacing a component in the chamber using the end effector with reference to a position of the end effector in a state where the feature is captured in the predetermined position in the image captured by the camera.

(Additional Statement 10)

A component replacement system comprising:
a processing device configured to process a substrate;
a component replacement device configured to replace a component in the processing device; and
a control device configured to control the processing device and the component replacement device,
wherein the processing device includes:
   a chamber in which the component is installed;
   a distance sensor disposed at the chamber; and
   a camera disposed at the chamber,
the component replacement device includes:
   a container; and
   a transfer arm disposed in the container and having an end effector at a tip end thereof, and
the control device executes:
a) connecting the component replacement device to the chamber;
b) inserting the end effector into the chamber and measuring a first distance from a predetermined position in the chamber to the end effector by the distance sensor;
c) moving the end effector until a difference between the first distance and a predetermined second distance is less than a predetermined third distance;
d) capturing a feature disposed at the end effector by the camera;
e) moving the end effector so that the feature is captured in a predetermined position in an image captured by the camera; and
f) replacing the component in the chamber using the end effector with reference to a position of the end effector in a state where the feature is captured in the predetermined position in the image captured by the camera.

### DESCRIPTION OF REFERENCE NUMERALS

W: substrate
100: plasma processing system
1: plasma processing apparatus
2: controller
10: plasma processing chamber
10a: sidewall
10b: opening
10c: gate valve
10d: window
10s: plasma processing space
11: substrate support
111: main body
112: ring assembly
13: shower head
13a: gas supply port
13b: gas diffusion space
13c: gas inlet port
13d: electrode support
13e: upper electrode
13f: holding mechanism
14: distance sensor
15: camera
20: gas supply device
30: power supply
40: exhaust system
50: component replacement device
51: container
52: cassette
53: transfer arm
530: end effector
54: moving mechanism
550: communication device
551: controller
56: distance sensor
57: camera
60: image
61: marker
62: region
65: image
66: marker
67: position
700: component replacement system
70: control device

1. A component replacement method comprising:
a) connecting a component replacement device to a chamber of a processing device configured to process a substrate;
b) inserting an end effector disposed at a tip end of a transfer arm in the component replacement device into the chamber, and measuring a first distance from a predetermined position in the chamber to the end effector using a distance sensor provided on the end effector;
c) moving the end effector until a difference between the first distance and a predetermined second distance becomes less than a predetermined third distance;
d) capturing a feature disposed at a predetermined position in the chamber by a camera provided on the end effector;
e) moving the end effector so that the feature is captured in a predetermined position in an image captured by the camera; and
f) replacing a component in the chamber using the end effector with reference to a position of the end effector in a state where the feature is captured in the predetermined position in the image captured by the camera.

2. The component replacement method of claim 1, wherein said step f) includes:
f1) removing a used component by the end effector;
f2) measuring a fourth distance from an installation position of an unused component in the chamber to the end effector using the distance sensor;
f3) moving the end effector until a difference between the fourth distance and a predetermined fifth distance becomes less than a predetermined sixth distance;
f4) capturing a feature disposed at the installation position by the camera;
f5) moving the end effector so that the feature disposed at the installation position is captured in the predetermined position in the image captured by the camera; and
f6) installing the unused component in the installation position using the end effector with reference to a position of the end effector in a state where the feature disposed at the installation position is captured in the predetermined position in the image captured by the camera.

3. The component replacement method of claim 2, further comprising:
g) cleaning the chamber,
wherein said step g) is executed between said step f1) and said step f6).

4. A component replacement method comprising:
a) connecting a component replacement device to a chamber of a processing device configured to process a substrate;
b) inserting an end effector disposed at a tip end of a transfer arm in the component replacement device into the chamber, and measuring a first distance from a predetermined position in the chamber to the end effector using a distance sensor disposed at the chamber;
c) moving the end effector until a difference between the first distance and a predetermined second distance becomes less than a predetermined third distance;
d) capturing a feature disposed at the end effector by a camera disposed at the chamber;
e) moving the end effector so that the feature is captured in a predetermined position in an image captured by the camera; and
f) replacing a component in the chamber using the end effector with reference to a position of the end effector in a state where the feature is captured in the predetermined position in the image captured by the camera.

5. The component replacement method of claim 4, further comprising:
g) cleaning the chamber,
wherein said step g) is executed after a used component is removed and before an unused component is installed in said step f).

6. The component replacement method of claim 3, wherein said step g) is further executed before said step b).

7.-10. (canceled)

11. The component replacement method of claim 5, wherein said step g) is further executed before said step b).

12. The component replacement method of claim 1, wherein said steps b) to e) are further executed at least once in that order before said step f).

13. The component replacement method of claim 4, wherein said steps b) to e) are further executed at least once in that order before said step f).

14. The component replacement method of claim 1, wherein the feature is an arrangement of a plurality of gas holes through which a gas supplied into the chamber flows.

15. The component replacement method of claim 4, wherein the feature is an arrangement of a plurality of gas holes through which a gas supplied into the chamber flows.

16. A component replacement device comprising:
a container;
a transfer arm disposed in the container and having an end effector; and
a controller,
wherein the end effector is provided with a distance sensor and a camera, and
the controller executes:
a) connecting the container to a chamber of a processing device configured to process a substrate;
b) inserting the end effector into the chamber and measuring a first distance from a predetermined position in the chamber to the end effector by the distance sensor;
c) moving the end effector until a difference between the first distance and a predetermined second distance becomes less than a predetermined third distance;
d) capturing a feature disposed at a predetermined position in the chamber by the camera;
e) moving the end effector so that the feature is captured in a predetermined position in an image captured by the camera; and
f) replacing a component in the chamber using the end effector with reference to a position of the end effector in a state where the feature is captured in the predetermined position in the image captured by the camera.

17. A component replacement system comprising:
a processing device configured to process a substrate;
a component replacement device configured to replace a component in the processing device; and
a control device configured to control the processing device and the component replacement device,
wherein the processing device includes:
a chamber in which the component is installed;
a distance sensor disposed at the chamber; and
a camera disposed at the chamber,
the component replacement device includes:
a container; and
a transfer arm disposed in the container and having an end effector at a tip end thereof, and
the control device executes:
a) connecting the component replacement device to the chamber;
b) inserting the end effector into the chamber and measuring a first distance from a predetermined position in the chamber to the end effector by the distance sensor;
c) moving the end effector until a difference between the first distance and a predetermined second distance is less than a predetermined third distance;
d) capturing a feature disposed at the end effector by the camera;
e) moving the end effector so that the feature is captured in a predetermined position in an image captured by the camera; and
f) replacing the component in the chamber using the end effector with reference to a position of the end effector in a state where the feature is captured in the predetermined position in the image captured by the camera.
